(19) United States
(12) Patent Application Publication
(10) Pub. No.: US 2023/0082246 A1
(43) Pub. Date: Mar. 16, 2023

(54) SUBSTRATE PROCESSING APPARATUS AND METHOD FOR MANUFACTURING SEMICONDUCTOR DEVICE

(71) Applicant: Kioxia Corporation, Tokyo (JP)

(72) Inventor: Kazuya YOSHIMORI, Yokkaichi (JP)

(73) Assignee: Kioxia Corporation, Tokyo (JP)

(21) Appl. No.: 17/654,118

(22) Filed: Mar. 9, 2022

(30) Foreign Application Priority Data
Sep. 16, 2021 (JP) 2021-151496

(51) Int. Cl. H01J 37/32; H01L 21/3065; H01L 21/308; H01L 21/32; H01J 37/34; C23C 14/34; C23C 14/04

(52) U.S. Cl. CPC H01J 37/32568; H01L 21/3065; H01L 21/308; H01L 21/32; H01J 37/32596; H01J 37/32541; H01J 37/32183; H01J 37/3438; C23C 14/34; C23C 14/042; H01J 2237/3341; H01J 2237/332; H01J 37/3211

(57) ABSTRACT

According to one embodiment, there is provided a substrate processing apparatus including a first electrode, a second electrode, a third electrode, a first power supply circuit, a second power supply circuit and a control line. The first electrode is arranged in a processing chamber, and on which a substrate can be placed. The second electrode faces the first electrode. The third electrode is arranged along a side wall in the processing chamber and facing the first electrode. The first power supply circuit is connected to the first electrode. The second power supply circuit is connected to the third electrode. The control line is connected to the first power supply circuit and the second power supply circuit.

### CROSS-REFERENCE TO RELATED APPLICATIONS

This application is based upon and claims the benefit of priority from Japanese Patent Application No. 2021-151496, filed on Sep. 16, 2021; the entire contents of which are incorporated herein by reference.

### FIELD

Embodiments described herein relate generally to a substrate processing apparatus, and a method for manufacturing a semiconductor device.

### BACKGROUND

In a process for manufacturing a semiconductor device, in a substrate processing apparatus, a predetermined process may be performed on a substrate placed in a processing chamber. In order to improve throughput for manufacturing the semiconductor device, it is desired that the substrate is efficiently processed in the substrate processing apparatus.

### BRIEF DESCRIPTION OF THE DRAWINGS

FIG. 1 is a diagram illustrating a schematic configuration of a substrate processing apparatus according to one embodiment;

FIG. 2 is a perspective view illustrating a configuration of a plurality of electrodes according to the embodiment;

FIGS. 3A and 3B are a plan view illustrating a configuration of a plurality of electrodes and a cross-sectional view illustrating a configuration of one electrode according to the embodiment;

FIG. 4 is a waveform diagram illustrating operations of the substrate processing apparatus according to the embodiment;

FIGS. 5A to 5D are cross-sectional views illustrating a processed shape by the substrate processing apparatus according to the embodiment;

FIG. 6 is a perspective view illustrating a configuration of a plurality of electrodes in a first modification of the embodiment;

FIG. 7 is a plan view illustrating the configuration of the plurality of electrodes in the first modification of the embodiment;

FIG. 8 is a diagram illustrating a configuration of a substrate processing apparatus according to a second modification of the embodiment;

FIG. 9 is a perspective view illustrating a configuration of a plurality of electrodes in the second modification of the embodiment;

FIG. 10 is a perspective view illustrating a configuration of a plurality of electrodes in a third modification of the embodiment; and

FIG. 11 is a diagram illustrating a configuration of a substrate processing apparatus according to a fourth modification of the embodiment.

### DETAILED DESCRIPTION

In general, according to one embodiment, there is provided a substrate processing apparatus including a first electrode, a second electrode, a third electrode, a first power supply circuit, a second power supply circuit and a control line. The first electrode is arranged in a processing chamber, and on which a substrate can be placed. The second electrode faces the first electrode. The third electrode is arranged along a side wall in the processing chamber and facing the first electrode. The first power supply circuit is connected to the first electrode. The second power supply circuit is connected to the third electrode. The control line is connected to the first power supply circuit and the second power supply circuit.

Exemplary embodiments of a substrate processing apparatus will be explained below in detail with reference to the accompanying drawings. The present invention is not limited to the following embodiments.

### Embodiments

The substrate processing apparatus according to the embodiment includes both an etching electrode and a film forming electrode. The etching includes dry etching such as reactive ion etching (RIE). The film formation includes physical film formation such as sputtering. For example, in the substrate processing apparatus, efficient processing of a substrate is achieved by devising how to drive the etching electrode and the film forming electrode.

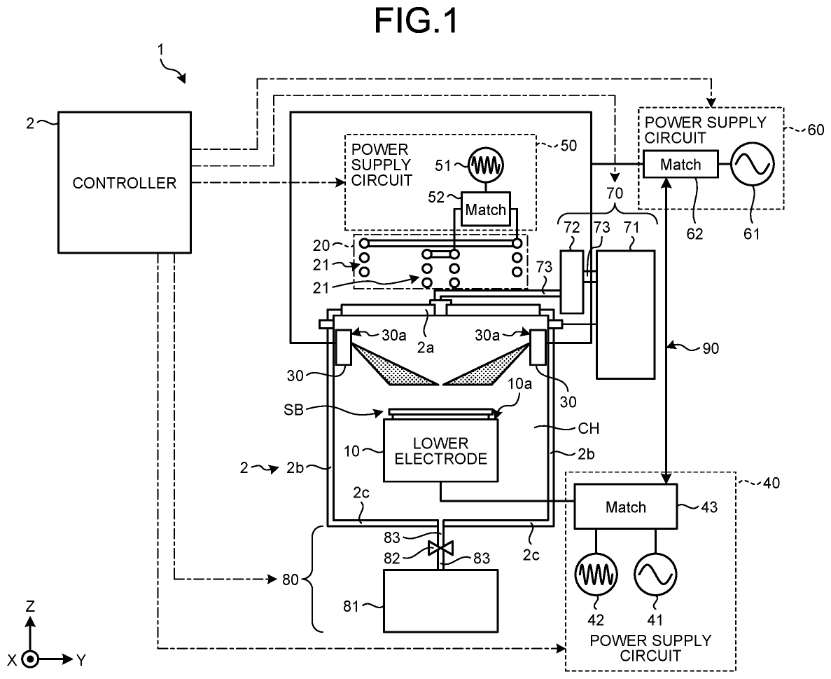

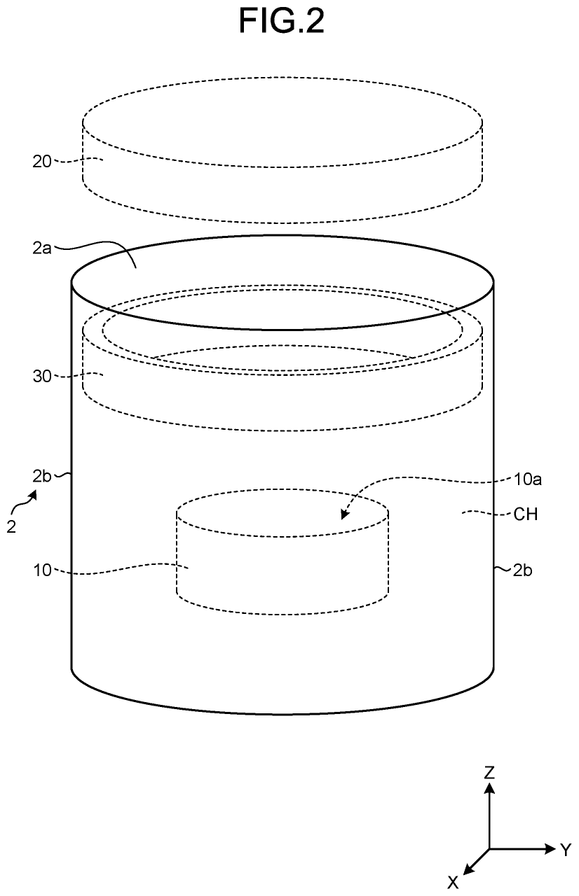

Specifically, a substrate processing apparatus 1 includes, as illustrated in FIGS. 1 and 2, a lower electrode 10, an upper electrode 20, a middle electrode 30, a power supply circuit 40, a power supply circuit 50, a power supply circuit 60, a gas supply system 70, an exhaust system 80, a control line 90, and a controller 2. FIG. 1 is a diagram illustrating a schematic configuration of the substrate processing apparatus 1. FIG. 2 is a perspective view illustrating a configuration of a plurality of electrodes (i.e., the lower electrode 10, the upper electrode 20, and the middle electrode 30). Hereinafter, a direction perpendicular to a surface 10a of the lower electrode 10 is referred to as a Z direction, and two directions orthogonal to each other in a plane perpendicular to the Z direction are referred to as an X direction and a Y direction.

The controller 2 integrally controls each component of the substrate processing apparatus 1. The controller 2 stores recipe information including processing procedures for a plurality of process parameters, and can control each component according to the recipe information. The plurality of process parameters include process parameters related to anisotropic etching conditions. The controller 2 may be arranged in the main body of the substrate processing apparatus 1, or may be provided outside the main body of the substrate processing apparatus 1 and communicably connected to each component of the substrate processing apparatus 1 via a wireless communication line or a wired communication line.

The lower electrode 10 is arranged in a processing chamber CH. The lower electrode 10 may have a substantially disk shape extending in the XY direction with the Z direction as the axis. A substrate SB to be treated can be placed on the surface (a surface on +Z-side) 10a of the lower electrode 10. The lower electrode 10 may be formed of a conductive material such as metal. The lower electrode 10 is used as both an etching electrode and a film forming electrode.

The processing chamber CH is a space formed by being surrounded by a vacuum vessel 2. The vacuum vessel 2 has a side wall 2b extending in a tube shape (for example, a cylindrical tube shape); a +Z-side end of the side wall 2b is closed by an upper wall 2a, and a −Z-side end of the side wall 2b is closed by a bottom wall 2c. The upper wall 2a may be formed of, for example, a dielectric.

The gas supply system 70 is configured to be able to supply a processing gas into the processing chamber CH. The gas supply system 70 includes a gas panel 71, a flow regulator 72, and a supply pipe 73. The supply pipe 73 communicates with the processing chamber CH through an opening provided in the upper wall 2a. The gas supply system 70 supplies, under the control of the controller 2, the processing gas stored in the gas panel 71 into the processing chamber CH through the supply pipe 73 while adjusting the flow rate of the processing gas by the flow regulator 72.

The exhaust system 80 is configured to be able to exhaust the processed processing gas from the processing chamber CH. The exhaust system 80 includes an exhaust device 81, a gate valve 82, and an exhaust pipe 83. The exhaust pipe 83 communicates with the processing chamber CH through an opening provided in the bottom wall 2c. The exhaust system 80 opens, under the control of the controller 2, the gate valve 82 so that the processed processing gas is exhausted from the processing chamber CH to the exhaust device 81.

The upper electrode 20 is arranged outside the processing chamber CH, on the +Z-side of the processing chamber CH. The upper electrode 20 may have a substantially disk shape extending in the XY direction with the Z direction as the axis. The upper electrode 20 is arranged on the +Z-side of the lower electrode 10 and faces the lower electrode 10 in the Z direction with the upper wall 2a interposed therebetween. The upper electrode 20 includes an antenna coil 21. The antenna coil 21 is formed by a conductive wire wound along a substantially disk shape extending in the XY direction with the Z direction as the axis. The antenna coil 21 is not illustrated in FIG. 2 for simplification. The upper electrode 20 is used as an etching electrode.

The middle electrode 30 is disposed in the processing chamber CH. The middle electrode 30 is arranged along the side wall 2b in the processing chamber CH. The middle electrode 30 may have a substantially cylindrical shape extending in the Z direction with the Z direction as the axis. The middle electrode 30 is disposed on the +Z-side of the lower electrode 10 and faces the lower electrode 10 in a direction inclined from the Z direction. The position of the middle electrode 30 in the Z direction may be between the position of the upper electrode 20 in the Z direction and the position of the lower electrode 10 in the Z direction.

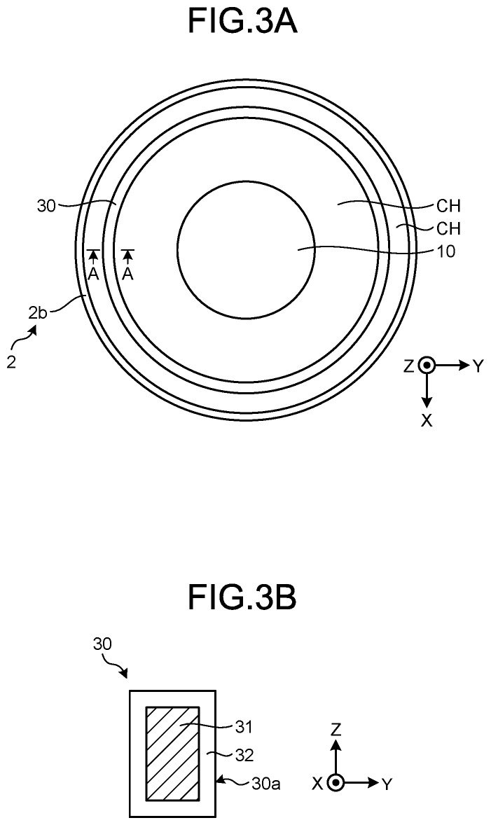

As illustrated in FIG. 3A, the middle electrode 30 surrounds the lower electrode 10 when viewed from the XY plane. FIG. 3A is an XY plan view illustrating a configuration of a plurality of electrodes (the lower electrode 10, and the middle electrode 30). The middle electrode 30 extends annularly along the side wall 2b inside the side wall 2b, when viewed from the XY plane. The lower electrode 10 is arranged in the vicinity of the center of the processing chamber CH. The middle electrode 30 is used as a film forming (for example, sputtering) electrode.

The power supply circuit 50 illustrated in FIG. 1 is connected to the upper electrode 20. The power supply circuit 50 can generate, under the control of the controller 2, radio frequency power and supply the radio frequency power to the upper electrode 20.

The power supply circuit 50 includes a source power supply 51 and a matching circuit 52. The source power supply 51 generates radio frequency power having a frequency FR1 and supplies the radio frequency power to the antenna coil 21. The frequency FR1 is a frequency suitable for plasma generation, and is, for example, 13.56 MHz. The matching circuit 52 performs impedance matching so that the impedance on the source power supply 51 side with respect to the matching circuit 52 and the impedance on the antenna coil 21 side with respect to the matching circuit 52 are equal. The antenna coil 21 uses the radio frequency power supplied in a state where the impedance matching is performed to generate an electromagnetic wave (radio frequency magnetic field). The electromagnetic wave generated by the antenna coil 21 passes through the upper wall 2a (dielectric wall) so as to be introduced into the space of the processing chamber CH. In the space of the processing chamber CH, the processing gas is discharged to generate plasma PL, and ions (for example, F+, CF3+, and/or the like) are generated from the processing gas together with radicals (F radical, CF radical, and/or the like).

The power supply circuit 40 is connected to the lower electrode 10. The power supply circuit 50 can generate, under the control of the controller 2, radio frequency power and supply the radio frequency power to the lower electrode 10.

The power supply circuit 40 includes a bias power supply 41, a source power supply 42, and a matching circuit 43. The bias power supply 41 generates radio frequency power having a frequency FR2 (relatively low frequency) and supplies the radio frequency power to the lower electrode 10. The frequency FR2 is lower than the frequency FR1. The frequency FR2 is a frequency suitable for ion acceleration, and is, for example, 2.0 MHz. The source power supply 42 can generate radio frequency power having the frequency FR1; however, the source power supply 42 is not used in the present embodiment. The matching circuit 43 performs impedance matching so that the impedance on the bias power supply 41 side with respect to the matching circuit 43 and the impedance on the lower electrode 10 side with respect to the matching circuit 43 are equal. The lower electrode 10 uses the radio frequency power having the frequency FR2 supplied in a state where the impedance matching is performed to accelerate the ions toward the lower electrode 10.

Thus, the substrate processing apparatus 1 can etch the substrate SB to be processed. At this time, a by-product can adhere to the middle electrode 30. The by-product may be a carbon component.

Here, the middle electrode 30 has, as illustrated in FIG. 3B, a main portion 31, and a surface portion 32 that completely covers the surface of main portion 31. FIG. 3B is a YZ cross-sectional view illustrating the configuration of the middle electrode 30, and is an enlarged cross-sectional view taken along line A-A of FIG. 3A. The main portion 31 may be formed of a conductive material such as metal. The surface portion 32 is formed of a material having dry etching resistance. The surface portion 32 may be formed of, for example, a ceramic material such as yttria (Y₂O₃), alumina (Al₂O₃), and zirconia (ZrO₂). The thickness of the surface portion 32 may be any thickness according to the dry etching resistance. A surface of the surface portion 32 on the lower electrode 10 side constitutes a surface 30a of the middle electrode 30. Thus, wear of the middle electrode 30 during the etching period can be suppressed. Although not illustrated in the drawings, the main portion 31 is electrically connected to the power supply circuit 60.

The power supply circuit 60 illustrated in FIG. 1 is connected to the middle electrode 30. The power supply circuit 60 can generate, under the control of the controller 2, radio frequency power and supply the radio frequency power to the middle electrode 30.

The power supply circuit 60 includes a sputtering power supply 61 and a matching circuit 62. The sputtering power supply 61 generates radio frequency power having a frequency FR3 and supplies the radio frequency power to the middle electrode 30. The frequency FR3 is lower than the frequency FR1 and lower than the frequency FR2. The frequency FR3 is a frequency suitable for sputtering, and is, for example, 100 kHz. The matching circuit 62 performs impedance matching so that the impedance on the sputtering power supply 61 side with respect to the matching circuit 62 and the impedance on the middle electrode 30 side with respect to the matching circuit 62 are equal. The middle electrode 30 uses the radio frequency power having the frequency FR3 supplied in a state where the impedance matching is performed to strike the ions on the middle electrode 30. Thus, the by-product adhered to the middle electrode 30 is sputtered toward the lower electrode 10.

The control line 90 illustrated in FIG. 1 is connected to the power supply circuit 40 and the power supply circuit 60. The control line 90 may be electrically connected between the matching circuit 43 and the matching circuit 62. The control line 90 is configured by, for example, a coaxial cable or the like, and can be configured by a conductive wire covered with insulation. Thus, the substrate processing apparatus 1 can switch between the power supply by the power supply circuit 40 and the power supply by the power supply circuit 60.

Specifically, the power supply circuit 40 and the power supply circuit 60 transmit and receive, via the control line 90, a synchronization signal related to at least one of the power supply by the power supply circuit 40 and the power supply by the second power supply circuit. The synchronization signal may be a pulse signal having a predetermined pulse width. The predetermined pulse width may be a pulse width with which the reception destination can identify the start of power supply and/or the stop of power supply.

For example, the matching circuit 43 may transmit, in response to the stop of power supply, a synchronization signal to the matching circuit 62 via the control line 90. According to the synchronization signal, the matching circuit 62 can grasp the timing at which the power supply circuit 40 stops power supply to the lower electrode 10, and can start impedance matching operation.

The matching circuit 62 may transmit, in response to the stop of power supply, a synchronization signal to the matching circuit 43 via the control line 90. According to the synchronization signal, the matching circuit 43 can grasp the timing at which the power supply circuit 60 stops power supply to the middle electrode 30, and can start impedance matching operation.

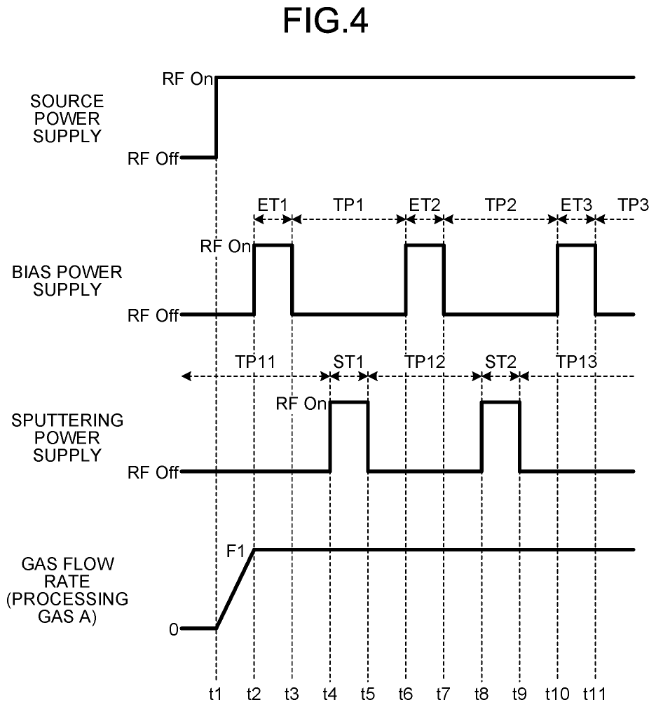

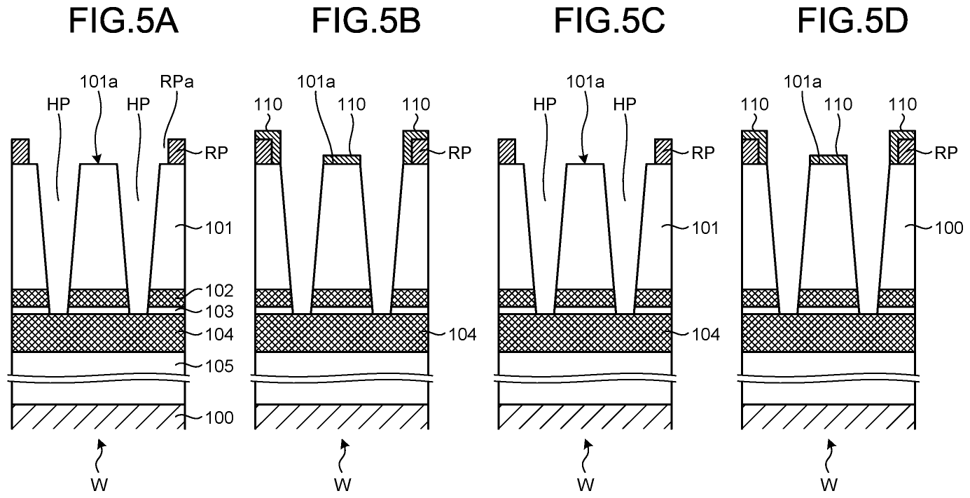

The operation of the substrate processing apparatus 1 will be described below with reference to FIG. 4 and FIGS. 5A to 5D. FIG. 4 is a waveform diagram illustrating the operation of the substrate processing apparatus 1. FIGS. 5A to 5D are cross-sectional views illustrating processed shapes by the substrate processing apparatus 1.

Before timing t1, a substrate W is placed on the lower electrode 10, and the exhaust system 80 exhausts the processing chamber CH so that the processing chamber CH is in a depressurized state.

At timing t1, the power supply circuit 50 performs impedance matching, and starts supplying radio frequency power having the frequency FR1 from the source power supply 51 to the upper electrode 20. At the same time, the gas supply system 70 starts to supply the processing gas into the processing chamber CH. Consequently, plasma is generated in the processing chamber CH.

After timing t1, a state in which the radio frequency power is supplied from the power supply circuit 50 to the upper electrode 20 is maintained, and a state in which the processing gas having a substantially constant gas flow rate F1 is supplied into the processing chamber CH is maintained. Consequently, a state in which plasma is generated in the processing chamber CH is maintained.

At timing t2, the power supply circuit 40 performs impedance matching, and starts supplying radio frequency power having the frequency FR2 from the bias power supply 41 to the lower electrode 10. Consequently, the substrate W starts to be etched in the processing chamber CH.

During the period from timing t2 to timing t3, etching processing of the substrate W as illustrated in FIG. 5A, for example, is performed. FIG. 5A illustrates a structure in which a semiconductor oxide film 105, a semiconductor film 104, a semiconductor oxide film 103, a semiconductor film 102, and a semiconductor oxide film 101 are stacked above a substrate 100 in this order from the side of the substrate 100. The semiconductor oxide film 101, the semiconductor oxide film 103, and the semiconductor oxide film 105 may each be formed of a material containing silicon oxide as a main component. The semiconductor film 102 and the semiconductor film 104 may each be formed of a material containing polysilicon as a main component. In this structure, a plurality of hole patterns HP penetrating the semiconductor oxide film 101 and the semiconductor film 102 are formed. In order to etch the bottom portions of the plurality of hole patterns HP, a resist material is applied, and a resist pattern RP having an opening RPa is formed.

When etching processing is performed under the condition of anisotropic etching using the resist pattern RP as a mask, immediately after the start of etching, a top portion 101a between the hole patterns HP in the semiconductor oxide film 101 is temporarily covered with a by-product film corresponding to the processing gas; however, when the semiconductor film 104 is exposed at the bottom portion of the hole patterns HP, the by-product film is etched and disappears. At this time, the by-product may adhere to the surface 30a of the middle electrode 30. The by-product contains, for example, a carbon component.

Thus, as illustrated in FIG. 5A, the top portion 101aof the semiconductor oxide film 101 is exposed. If the etching is continued in this state, the top portion 101a may be etched to cause a pattern defect. Since the top portion 101a has a small dimension, it is difficult to apply a resist material, so that it is difficult to cover and protect the top portion 101a with a resist pattern.

At timing t3 illustrated in FIG. 4, the power supply circuit 40 stops supplying the radio frequency power to the lower electrode 10. Consequently, the etching of the substrate W in the processing chamber CH is stopped.

The power supply circuit 40 transmits, in response to the stop of power supply, a synchronization signal to the power supply circuit 60 via the control line 90. The power supply circuit 60 receives the synchronization signal via the control line 90. According to the received synchronization signal, the power supply circuit 60 can recognize that the power supply circuit 40 has stopped supplying power to the lower electrode 10.

At timing t4 when a predetermined time has elapsed since the synchronization signal was received, the power supply circuit 60 performs impedance matching, and starts supplying the radio frequency power having the frequency FR3 from the sputtering power supply 61 to the middle electrode 30.

Thus, in the period from timing t4 to timing t5, the by-product is deposited (sputtered) from the middle electrode 30 to the lower electrode 10, and a by-product film (for example, a film containing a carbon component) 110 is formed on the substrate W, as illustrated in FIG. 5B. The by-product film 110 covers the upper surface and the side surface of the resist pattern RP and covers the surface of the top portion 101a. Therefore, the by-product film 110 can function as an etching protection film at the time of etching. In other words, the by-product film 110 can be prepared as an etching protection film for the next etching.

At timing t5, the power supply circuit 60 stops supplying the radio frequency power to the middle electrode 30. Consequently, the sputtering of the substrate W in the processing chamber CH is stopped.

The power supply circuit 60 transmits, in response to the stop of power supply, a synchronization signal to the power supply circuit 40 via the control line 90. The power supply circuit 40 receives the synchronization signal via the control line 90. According to the received synchronization signal, the power supply circuit 40 can recognize that the power supply circuit 60 has stopped supplying power to the middle electrode 30.

At timing t6 when a predetermined time has elapsed since the synchronization signal was received, the power supply circuit 40 performs impedance matching, and starts supplying radio frequency power of the frequency FR2 from the bias power supply 41 to the lower electrode 10. Consequently, the substrate W starts to be etched in the processing chamber CH.

During the period from timing t6 to timing t7, etching processing of the substrate W as illustrated in FIG. 5C, for example, is performed. Immediately after the start of etching, the top portion 101a between the hole patterns HP in the semiconductor oxide film 101 is covered with the by-product film 110; however, as the etching of the semiconductor film 104 proceeds, the by-product film 110 is etched and disappears.

At timing t7 illustrated in FIG. 4, the power supply circuit 40 stops supplying the radio frequency power to the lower electrode 10. Consequently, the etching of the substrate W in the processing chamber CH is stopped.

The power supply circuit 40 transmits, in response to the stop of power supply, a synchronization signal to the power supply circuit 60 via the control line 90. The power supply circuit 60 receives the synchronization signal via the control line 90. According to the received synchronization signal, the power supply circuit 60 can recognize that the power supply circuit 40 has stopped supplying power to the lower electrode 10.

At timing t8 when a predetermined time has elapsed since the synchronization signal was received, the power supply circuit 60 performs impedance matching, and starts supplying the radio frequency power having the frequency FR3 from the sputtering power supply 61 to the middle electrode 30.

Thus, in the period from timing t8 to timing t9, the by-product is deposited (sputtered) from the middle electrode 30 to the lower electrode 10, and the by-product film 110 is formed on the substrate W, as illustrated in FIG. 5D. Since the by-product film 110 covers the top portion 101a, it can function as an etching protection film at the time of etching. In other words, the by-product film 110 can be prepared as an etching protection film for the next etching.

After timing t10, operations similar to those at timing t6 to timing t10 are repeated.

A period ET1 from timing t2 to timing t3, a period ET2 from timing t6 to timing t7, and a period ET3 from timing t10 to timing t11 illustrated in FIG. 4 are etching periods in which etching is performed. A period TP1 from timing t3 to timing t6, a period TP2 from timing t7 to timing t10, and a period TP3 after timing t11 are etching stop periods in which etching is stopped.

A period ST1 from the timing t4 to the timing t5 and a period ST2 from the timing t8 to the timing t9 are sputtering periods in which sputtering is performed. A period TP11 from the timing t1 to the timing t4, a period TP12 from the timing t5 to the timing t8, and a period TP13 after the timing t9 are sputtering stop periods in which sputtering period is stopped.

The etching periods ET1, ET2, and ET3 are included in the sputtering stop periods TP11, TP12, and TP13, respectively. The sputtering periods ST1 and ST2 are included in the etching stop periods TP1 and TP2, respectively. In other words, the substrate processing apparatus 1 can perform etching and sputtering alternately and exclusively. For example, switching between etching and sputtering can be performed at high speed (for example, a speed comparable to a pulse frequency).

As described above, in the embodiment, in the substrate processing apparatus 1, the power supply circuit 40 and the power supply circuit 60 are connected via the control line 90. The power supply circuit 40 and the power supply circuit 60 transmit and receive, via the control line 90, a synchronization signal related to at least one of the power supply by the power supply circuit 40 and the power supply by the power supply circuit 60. In response to the synchronization signal, the power supply circuit 40 and the power supply circuit 60 synchronize the power supply by the power supply circuit 40 and the power supply by the power supply circuit 60. Thus, it is possible to alternately perform etching and film formation (for example, sputtering) while maintaining the supply of the same processing gas into the processing chamber CH, and therefore it is possible to efficiently perform etching processing for a plurality of closely arranged hole patterns that are difficult to mask with a resist pattern, for example. In other words, the substrate W can be efficiently processed.

For example, in a case where an etching protection film corresponding to the by-product film is deposited on the substrate W by In-situ atomic layer deposition (ALD), since a processing gas different from that used for etching is used, the processing is put on standby during an operation time when the gas supply system 70 switches the processing gas. Thus, throughput for processing the substrate W decreases, so that productivity in a method for manufacturing a semiconductor device including the processing of the substrate W may decrease.

In contrast, in the embodiment, it is possible to alternately perform etching and film formation (for example, sputtering) while maintaining the supply of the same processing gas into the processing chamber CH. Thus, when etching is performed substantially with no dry etching mask without being able to apply a resist or the like, productivity of the method for manufacturing the semiconductor device including the processing of the substrate W can be improved.

The lower electrode 10 may have another shape, instead of being limited to the substantially disk shape extending in the XY direction with the Z direction as the axis. The lower electrode 10 may have a substantially rectangular parallelepiped shape extending in the XY direction with the Z direction as the axis.

The upper electrode 20 may have another shape, instead of being limited to the substantially disk shape extending in the XY direction with the Z direction as the axis. The upper electrode 20 may have a substantially rectangular parallelepiped shape extending in the XY direction with the Z direction as the axis.

The middle electrode 30 may have another shape, instead of being limited to the substantially cylindrical shape extending in the Z direction with the Z direction as the axis. The middle electrode 30 may have a substantially rectangular tube shape extending in the Z direction with the Z direction as the axis. In this case, the middle electrode 30 extends in a rectangular annular shape when viewed from the XY plane.

The middle electrode 30 may be provided with a temperature control mechanism. With such a configuration, the adhesion amount of the by-product to the middle electrode 30 can be adjusted.

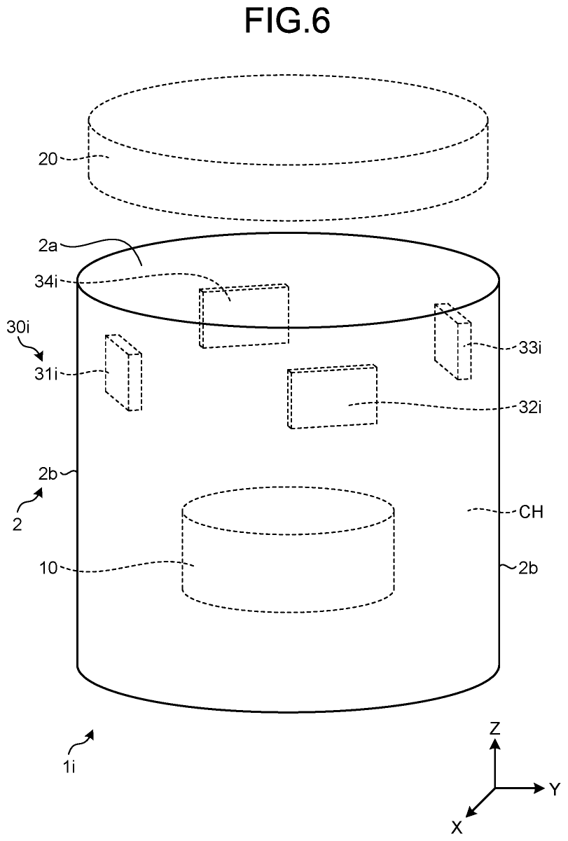

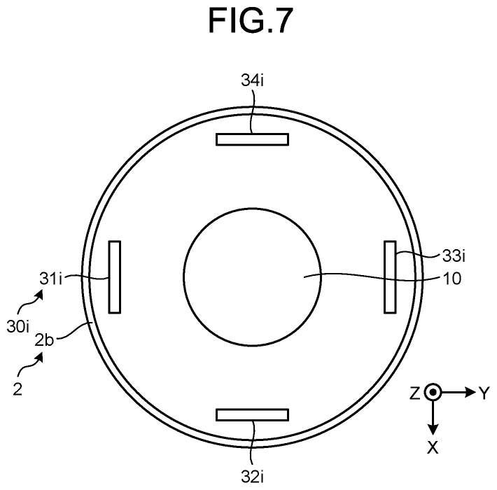

Alternatively, a middle electrode 30i of a substrate processing apparatus li may be divided into a plurality of sub-electrodes 31i to 34i as illustrated in FIGS. 6 and 7. FIG. 6 is a perspective view illustrating a configuration of a plurality of electrodes (the lower electrode 10, the upper electrode 20, and the middle electrode 30i) according to a first modification of the embodiment. FIG. 7 is a plan view illustrating a configuration of the plurality of electrodes (the lower electrode 10 and the middle electrode 30i) in the first modification of the embodiment. FIGS. 6 and 7 illustrate a case where the middle electrode 30i is divided into four sub-electrodes 31i to 34i; however, the number of divisions may also be two, three, five, or more than five.

For example, the sub-electrodes 31i to 34i illustrated in FIGS. 6 and 7 can be configured by removing portions corresponding to spaces between the sub-electrodes 31i to 34i from the middle electrode 30 illustrated in FIGS. 2 and 3. By configuring the middle electrode 30i with the plurality of divided sub-electrodes 31i to 34i, the electrode material can be saved, so that the cost of the substrate processing apparatus li can be reduced.

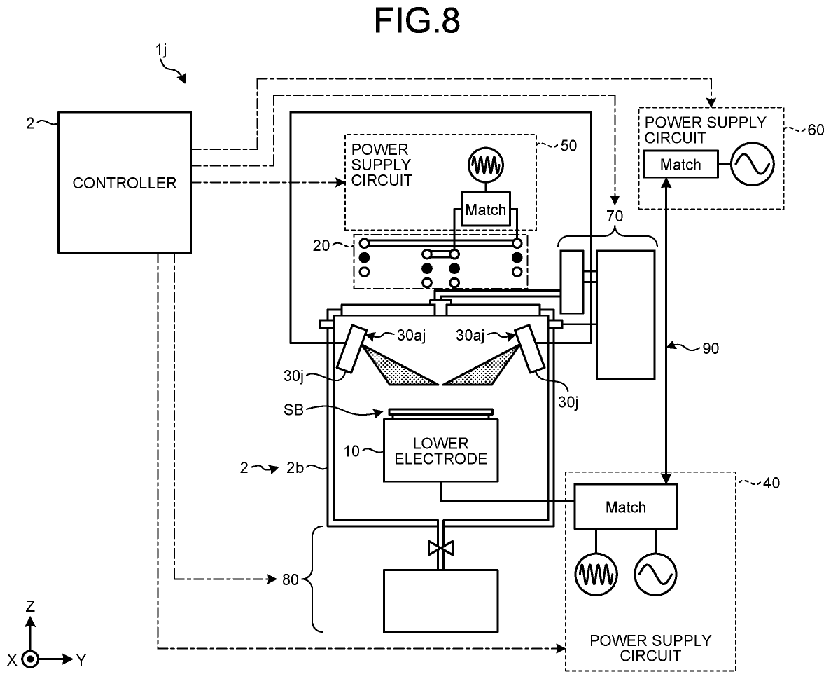

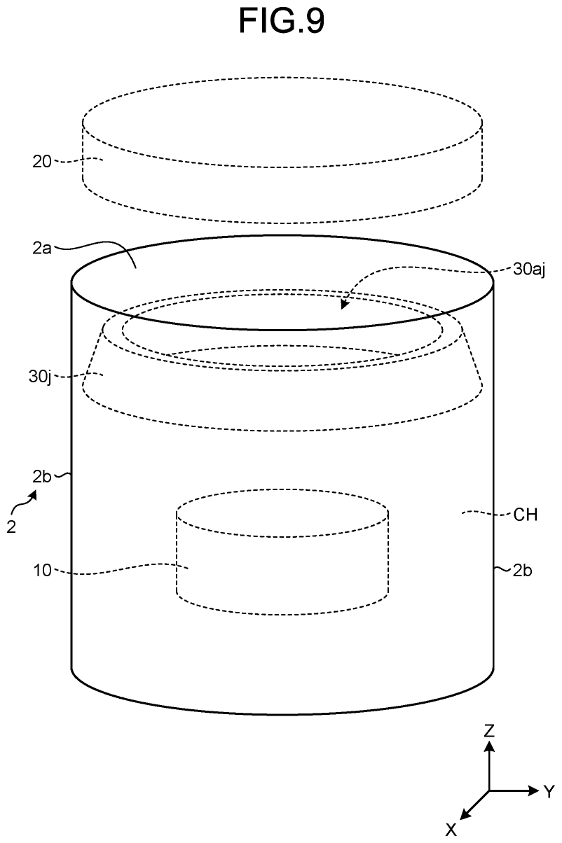

Alternatively, a middle electrode 30j of a substrate processing apparatus 1j may be configured such that a surface 30aj thereof is inclined in a direction facing the lower electrode 10 with respect to the side wall 2b, as illustrated in FIGS. 8 and 9. FIG. 8 is a diagram illustrating a configuration of the substrate processing apparatus 1j according to a second modification of the embodiment. FIG. 9 is a perspective view illustrating a configuration of a plurality of electrodes (the lower electrode 10 and the middle electrode 30j) according to the second modification of the embodiment.

The middle electrode 30j may have a substantially hollow truncated cone shape in which the width in the XY direction decreases toward the +Z direction with the Z direction as the axis. An inner surface of the substantially hollow truncated cone shape constitutes the surface 30aj of the middle electrode 30j. The surface 30aj is inclined in a direction toward the lower electrode 10. With such a configuration, in sputtering, when ions of the processing gas are struck against the surface 30aj of the middle electrode 30j, the by-product adhering to the surface 30aj of the middle electrode 30j is more likely to be sputtered to the substrate W on the lower electrode 10.

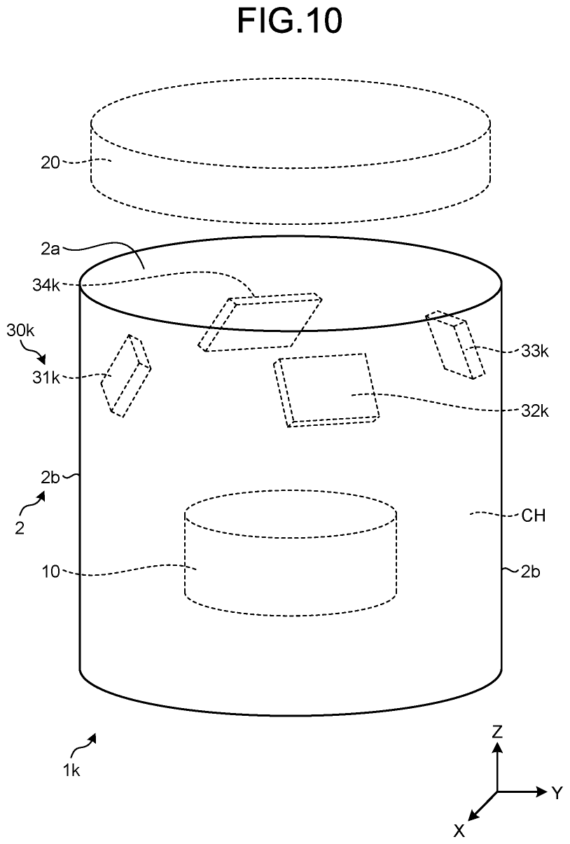

Alternatively, a middle electrode 30k of a substrate processing apparatus 1k may be divided into a plurality of sub-electrodes 31k to 34k as illustrated in FIG. 10. FIG. 10 is a perspective view illustrating a configuration of a plurality of electrodes (the lower electrode 10, the upper electrode 20, and the middle electrode 30k) according to a third modification of the embodiment. FIG. 10 illustrates a case where the middle electrode 30k is divided into four sub-electrodes 31k to 34k; however, the number of divisions may also be two, three, five, or more than five.

For example, the sub-electrodes 31k to 34k illustrated in FIG. 10 can be configured by removing portions corresponding to spaces between the sub-electrodes 31k to 34k from the middle electrode 30j illustrated in FIGS. 8 and 9. By configuring the middle electrode 30k with the plurality of divided sub-electrodes 31k to 34k, the electrode material can be saved, so that the cost of the substrate processing apparatus 1k can be reduced.

The above embodiment is described based on an example in which the substrate processing apparatus 1 configured by adding a film forming electrode and a power supply circuit to a configuration corresponding to an inductive coupling plasma (ICP) type RIE apparatus; however, the substrate processing apparatus 1 is not limited to this configuration. For example, the substrate processing apparatus 1 may be configured by adding a film forming electrode and a power supply circuit to a configuration corresponding to an electron cycrotron resonance (ECR) type RIE apparatus.

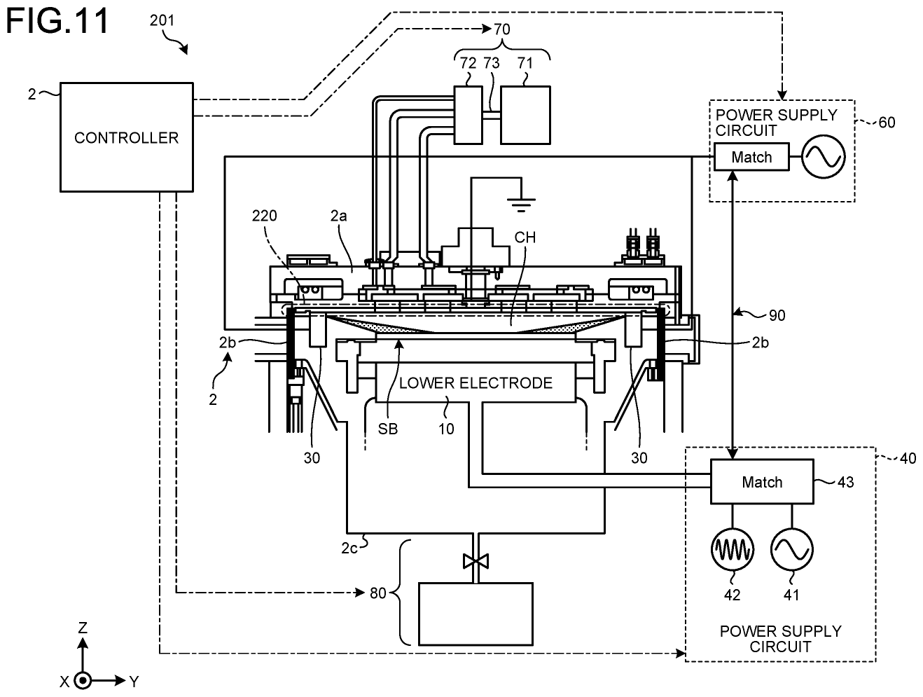

Alternatively, a substrate processing apparatus 201 may be configured by adding the middle electrode 30 and the power supply circuit 60 for film formation to a configuration corresponding to a two-frequency parallel plate type (capacitive coupling type) RIE apparatus, as illustrated in FIG. 11. FIG. 11 is a diagram illustrating a configuration of the substrate processing apparatus 201 according to a fourth modification of the embodiment.

The substrate processing apparatus 201 includes an upper electrode 220 instead of the upper electrode 20 (see FIG. 1), and the power supply circuit 50 (see FIG. 1) is omitted. The upper electrode 220 is connected to the ground potential.

The upper electrode 220 is arranged in the processing chamber CH so as to face the lower electrode 10. The upper electrode 220 is arranged in the processing chamber CH, on the +Z-side of the lower electrode 10, and extends in the XY direction. The upper electrode 220 is provided with an opening penetrating in the Z direction. The supply pipe 73 of the gas supply system 70 communicates with the processing chamber CH via the opening provided in the upper wall 2a and the opening provided in the upper electrode 220.

The source power supply 42, instead of the source power supply 51 (see FIG. 1), is used as a source power supply for plasma generation. In the power supply circuit 40, the matching circuit 43 can perform impedance matching for the source power supply 42 in addition to impedance matching for the bias power supply 41. In the impedance matching for the source power supply 42, the matching circuit 43 performs impedance matching so that the impedance on the source power supply 42 side with respect to the matching circuit 43 and the impedance on the lower electrode 10 side with respect to the matching circuit 43 are equal.

For example, at timing t1 illustrated in FIG. 4, the power supply circuit 40 performs impedance matching for the source power supply 42, and starts supplying radio frequency power of the frequency FR1 from the source power supply 42 to the lower electrode 10. After timing t1, the power supply circuit 40 maintains a state in which the impedance matching for the source power supply 42 is performed. In other words, the power supply from the source power supply 42 to the lower electrode 10 is maintained, and the generation of plasma in the processing chamber CH is maintained.

On the other hand, at timing t2, the power supply circuit 40 performs impedance matching, and starts supplying radio frequency power having the frequency FR2 from the bias power supply 41 to the lower electrode 10. In other words, the power supply from the bias power supply 41 to the lower electrode 10 is started. Consequently, the substrate W starts to be etched in the processing chamber CH.

At timing t3, the power supply circuit 40 stops supplying the radio frequency power having the frequency FR2 to the lower electrode 10. In other words, the supply of power (etching power) from the bias power supply 41 to the lower electrode 10 is stopped. Consequently, the etching of the substrate W in the processing chamber CH is stopped.

The fourth modification of the embodiment is similar to the embodiment in that the power supply circuit 40 transmits a synchronization signal to the power supply circuit 60 via the control line 90 in response to the stop of power supply, and the power supply circuit 60 transmits a synchronization signal to the power supply circuit 40 via the control line 90 in response to the stop of power supply.

In such a manner, in the substrate processing apparatus 201, the power supply circuit 40 and the power supply circuit 60 also transmit and receive, via the control line 90, a synchronization signal related to at least one of the supply of power (sputtering power) by the power supply circuit 40 and the supply of power (etching power) by the power supply circuit 60. In response to the synchronization signal, the power supply circuit 40 and the power supply circuit 60 synchronize the power supply by the power supply circuit 40 and the power supply by the power supply circuit 60. Thus, it is possible to alternately perform etching and film formation (for example, sputtering) while maintaining the supply of the same processing gas into the processing chamber CH, and therefore it is possible to efficiently perform etching processing for a plurality of closely arranged hole patterns that are difficult to mask with a resist pattern, for example. In other words, the substrate W can be efficiently processed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing apparatus comprising:
a first electrode that is arranged in a processing chamber, and on which a substrate can be placed;
a second electrode facing the first electrode;
a third electrode arranged along a side wall in the processing chamber and facing the first electrode;
a first power supply circuit connected to the first electrode;
a second power supply circuit connected to the third electrode; and
a control line connected to the first power supply circuit and the second power supply circuit.

2. The substrate processing apparatus according to claim 1, wherein
the third electrode is arranged between the first electrode and the second electrode in a direction along the side wall.

3. The substrate processing apparatus according to claim 1, wherein
a surface of the third electrode is covered with a material having etching resistance.

4. The substrate processing apparatus according to claim 1, wherein
the third electrode surrounds the first electrode in plan view.

5. The substrate processing apparatus according to claim 1, wherein
a surface of the third electrode extends in a direction along the side wall.

6. The substrate processing apparatus according to claim 1, wherein
a surface of the third electrode extends obliquely in a direction facing the first electrode with respect to the side wall.

7. The substrate processing apparatus according to claim 5, wherein
the third electrode has a substantially cylindrical surface shape.

8. The substrate processing apparatus according to claim 5, wherein
the third electrode includes a plurality of sub-electrodes obtained by dividing a substantially cylindrical surface shape in a circumferential direction.

9. The substrate processing apparatus according to claim 6, wherein
the third electrode has a substantially hollow truncated cone shape.

10. The substrate processing apparatus according to claim 6, wherein
the third electrode includes a plurality of sub-electrodes obtained by dividing a substantially hollow truncated cone shape in a circumferential direction.

11. The substrate processing apparatus according to claim 1, wherein
the substrate processing apparatus can switch between power supply by the first power supply circuit and power supply by the second power supply circuit.

12. The substrate processing apparatus according to claim 1, wherein
the first power supply circuit and the second power supply circuit transmit and receive, via the control line, a signal related to at least one of power supply by the first power supply circuit and power supply by the second power supply circuit, and synchronize the power supply by the first power supply circuit and the power supply by the second power supply circuit in response to the signal.

13. The substrate processing apparatus according to claim 12, wherein
the first power supply circuit generates power during a period in which the power supply by the second power supply circuit is stopped, and
the second power supply circuit generates power during a period in which the power supply by the first power supply circuit is stopped.

14. The substrate processing apparatus according to claim 12, further comprising:
a third power supply circuit connected to the second electrode,
wherein, in the substrate processing apparatus, the power supply by the first power supply circuit and the power supply by the second power supply circuit are synchronized with each other while power supply by the third power supply circuit is maintained.

15. The substrate processing apparatus according to claim 1, wherein
the first power supply circuit is capable of generating a power at a first frequency, and
the second power supply circuit is capable of generating a power at a second frequency lower than the first frequency.

16. The substrate processing apparatus according to claim 14, wherein
the first power supply circuit is capable of generating a power at a first frequency,
the second power supply circuit is capable of generating a power at a second frequency lower than the first frequency, and
the third power supply circuit is capable of generating a power at a third frequency higher than the first frequency.

17. The substrate processing apparatus according to claim 1, wherein
the second electrode is arranged outside the processing chamber.

18. The substrate processing apparatus according to claim 1, wherein
the second electrode is arranged in the processing chamber.

19. A method for manufacturing a semiconductor device, comprising:
processing a substrate using a resist pattern as a mask in a state where a first processing gas is supplied to the substrate; and
depositing a by-product on the substrate in a state where the first processing gas is supplied to the substrate.

20. The method for manufacturing the semiconductor device according to claim 19, wherein
the processing of the substrate and the deposition of the by-product are alternately performed while maintaining a state where the first processing gas is supplied to the substrate.
